(19) United States
(12) Patent Application Publication
(10) Pub. No.: US 2026/0068108 A1
(43) Pub. Date: Mar. 5, 2026

(54) CIRCUIT CONNECTION DEVICE

(71) Applicant: Luxshare Precision Industry Company Limited, SHENZHEN, Guangdong Province (CN)

(72) Inventors: Xing-Ran TANG, SHENZHEN (CN); Yun-Bo LINGHU, SHENZHEN (CN); Pei-Quan LIN, SHENZHEN (CN); Xiang-Feng SHEN, SHENZHEN (CN)

(73) Assignee: Luxshare Precision Industry Company Limited, SHENZHEN, Guangdong Province (CN)

(21) Appl. No.: 18/932,264

(22) Filed: Oct. 30, 2024

(30) Foreign Application Priority Data
Aug. 30, 2024 (CN) 202411220628.2

(51) Int. Cl. H05K 7/20; B60L 53/16; B60L 53/18

(52) U.S. Cl. CPC H05K 7/20872; B60L 53/16; B60L 53/18; H05K 7/20272

(57) ABSTRACT

A circuit connection device includes a first conductive terminal, a cable and a first fixed joint. The first conductive terminal is provided with a first receiving socket and a first guide channel in communication with the first receiving socket. The first guide channel is in communication with the outside via a first external connector. One end of the cable is inserted into the first receiving socket, the cable is provided with a communication channel, the communication channel is in communication with the outside through a first communication port, and the first communication port is located in the first receiving socket. The first fixed joint is sleeved on the cable and connected to the first conductive terminal, and the first receiving socket forms a first cooling cavity enclosed by the first fixed joint.

### CROSS-REFERENCE TO RELATED APPLICATION(S)

This application claims priority to Chinese Patent Application No. 202411220628.2 filed Aug. 30, 2024, the disclosure of which is incorporated herein by reference in its entirety.

### TECHNICAL FIELD

This application relates to the field of liquid-cooled charging technology, and in particular to a circuit connection device.

### BACKGROUND

In a liquid-cooled charging system, a conductive terminal with a large overload current is the largest heat point, and the local maximum temperature rise of the conductive terminal with a large overload current limits the maximum current and charging time of the liquid-cooled charging system.

In the related art, the cooling pipeline in the liquid-cooled charging system cools the conductive terminal on its outer side, and the contact area of the cooling pipeline with the conductive terminal is limited, resulting in low heat transfer efficiency. The liquid cooling medium cannot take away the heat on the conductive terminal in time, affecting the normal operation of the liquid-cooled charging system, and the conductive terminal further needs to be equipped with multiple components to limit the position of the cooling pipeline and accommodate the cooling pipeline. The overall assembly process is complicated, occupies a large space, and is not easy to disassemble and maintain.

### SUMMARY

Embodiments of the present application provide a circuit connection device.

A circuit connection device includes: a first conductive terminal, a cable and a first fixed joint.

The first conductive terminal is provided with a first receiving socket and a first guide channel in communication with the first receiving socket. The first guide channel is in communication with the outside of the circuit connection device via a first external connector.

One end of the cable is inserted into the first receiving socket, the cable is provided with a communication channel, the communication channel is in communication with the outside of the circuit connection device through a first communication port, and the first communication port is located in the first receiving socket.

The first fixed joint is sleeved on the cable and connected to the first conductive terminal, and the first receiving socket forms a first cooling cavity enclosed by the first fixed joint.

In some embodiments, the cable includes a metal tube body and a support member arranged in the metal tube body, and an inner cavity of the metal tube body is supported by the support member to form the communication channel.

In some embodiments, the first receiving socket includes a first cooling socket body and a first plug-in socket body arranged at the bottom of the first cooling socket body, a first end of the metal tube body is plugged into the first plug-in socket body, and the first cooling socket body forms the first cooling cavity enclosed by the first fixed joint.

In some embodiments, the first end of the metal tube body is enclosed, and the first communication port is arranged in a side wall of the metal tube body, and is located in the first cooling socket body.

In some embodiments, the first fixed joint includes a first positioning part and a first connecting part connected to each other, the first positioning part is sleeved on the cable, and the first connecting part is sleeved on the first conductive terminal.

In some embodiments, the circuit connection device further includes a first sealing ring. The first sealing ring is sleeved on the cable and sandwiched between the first conductive terminal and the first positioning part.

In some embodiments, the circuit connection device further includes a feeding pipeline. Two first conductive terminals are provided, each of the first conductive terminals is provided with one cable and one first fixed joint, the feeding pipeline has one inlet and two outlets, and the two outlets are communicated with two first external connectors in one-to-one correspondence.

In some embodiments, the circuit connection device further includes a second conductive terminal and a second fixed joint.

The second conductive terminal is provided with a second receiving socket and a second guide channel in communication with the second receiving socket. The second guide channel is in communication with the outside of the circuit connection device via a second external connector, the other end of the cable is inserted into the second receiving socket, the communication channel is in communication with the outside of the circuit connection device through the second communication port, and the second communication port is located in the second receiving socket.

The second fixed joint is sleeved on the cable and connected to the second conductive terminal. The second receiving socket forms a second cooling cavity enclosed by the second fixed joint. The first guide channel, the first cooling cavity, the communication channel, the second cooling cavity and the second guide channel are in communication in sequence to form a cooling pipeline In some embodiments, the second fixed joint includes a second positioning part and a second connecting part connected to each other, the second positioning part is sleeved on the cable, and the second connecting part is sleeved on the second conductive terminal.

In some embodiments, the circuit connection device further includes a second sealing ring. The second sealing ring is sleeved on the cable and sandwiched between the second conductive terminal and the second positioning part.

### BRIEF DESCRIPTION OF DRAWINGS

FIG. 1 is a schematic structural diagram of a circuit connection device according to one or more embodiments of the present application;

FIG. 2 is a schematic diagram showing partial structure of the circuit connection device according to one or more embodiments of the present application;

FIG. 3 is a sectional view one showing partial structure of the circuit connection device according to one or more embodiments of the present application;

FIG. 4 is a schematic structural diagram of a first conductive terminal according to one or more embodiments of the present application;

FIG. 5 is a sectional view of the first conductive terminal according to one or more embodiments of the present application;

FIG. 6 is a sectional view two showing partial structure of the circuit connection device according to one or more embodiments of the present application;

FIG. 7 is a schematic structural diagram of a second conductive terminal according to one or more embodiments of the present application; and

FIG. 8 is a sectional view of the second conductive terminal according to one or more embodiments of the present application.

### REFERENCE NUMERALS IN THE DRAWINGS

1 first conductive terminal
11 first receiving socket
111 first cooling socket body
112 first plug-in socket body
113 first cooling cavity
12 first guide channel
121 first external connector
2 cable
21 metal tube body
211 communication channel
212 first communication port
213 second communication port
22 support member
23 outer sheath
3 first fixed joint
31 first positioning part
32 first connecting part
4 first sealing ring
5 feeding pipeline
6 second conductive terminal
61 second receiving socket
611 second cooling socket body
612 second plug-in socket body
613 second cooling cavity
62 second guide channel
621 second external connector
7 second fixed joint
71 second positioning part
72 second connecting part
8 second sealing ring

### DETAILED DESCRIPTION

The embodiments of the present application are described in detail below. Examples of the embodiments are shown in the accompanying drawings, in which the same or similar reference numerals throughout represent the same or similar parts or parts with the same or similar functions. The embodiments described below with reference to the accompanying drawings are exemplary, are intended to be used to explain the present application, and should not be understood as limiting the present application.

In the description of the present application, it is to be noted that, unless otherwise expressly specified and limited, the terms “connected to each other”, “connected” or “fixed” are to be construed in a broad sense, for example, as permanently connected or detachably connected; mechanically connected or electrically connected; directly connected to each other or indirectly connected to each other via an intermediary; or internally connection of two components or interaction relationship between two components. For those of ordinary skill in the art, specific meanings of the preceding terms in the present application may be construed based on specific situations.

In the description of the present application, unless otherwise expressly specified and limited, when a first feature is described as “above” or “below” a second feature, the first feature and the second feature may be in direct contact, or be in contact via another feature between the two features. Moreover, when the first feature is described as “on”, “above” or “over” the second feature, the first feature is right on, above or over the second feature or the first feature is obliquely on, above or over the second feature; or the first feature is simply at a higher level than the second feature. When the first feature is described as “under”, “below” or “underneath” the second feature, the first feature is right under, below or underneath the second feature or the first feature is obliquely under, below or underneath the second feature, or the first feature is simply at a lower level than the second feature.

The technical solution of the present application is further described below in conjunction with the accompanying drawings and through specific embodiments.

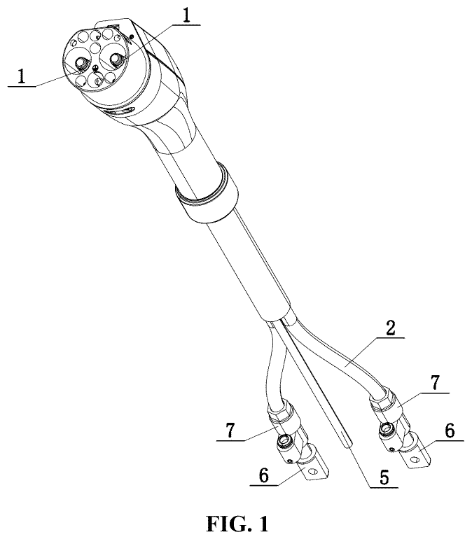

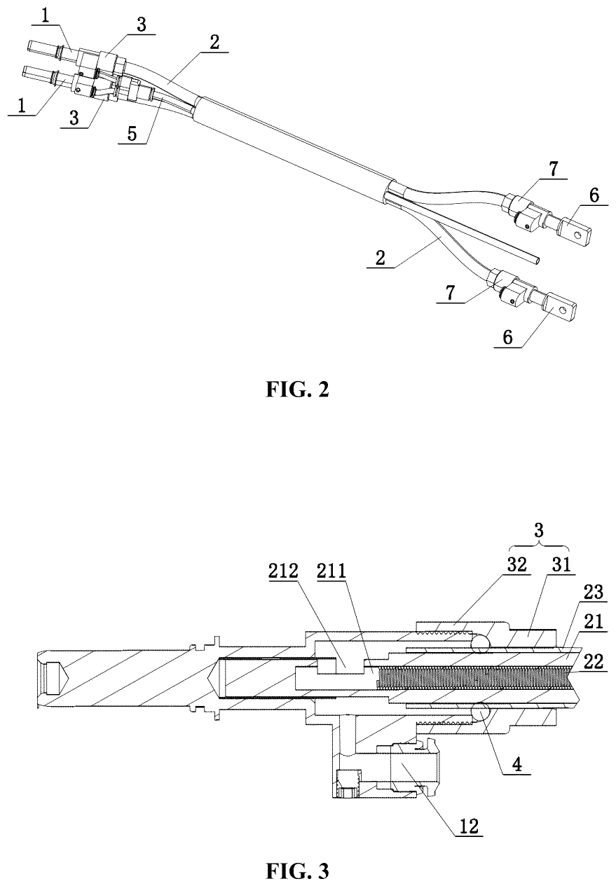

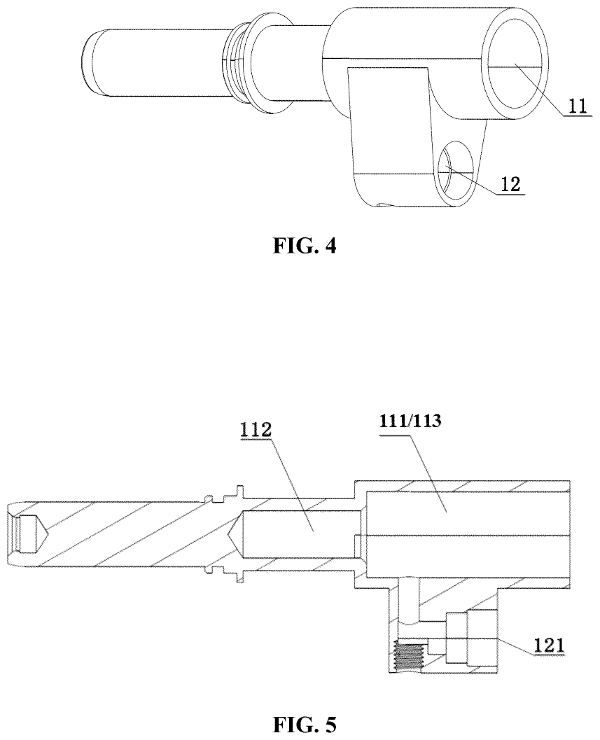

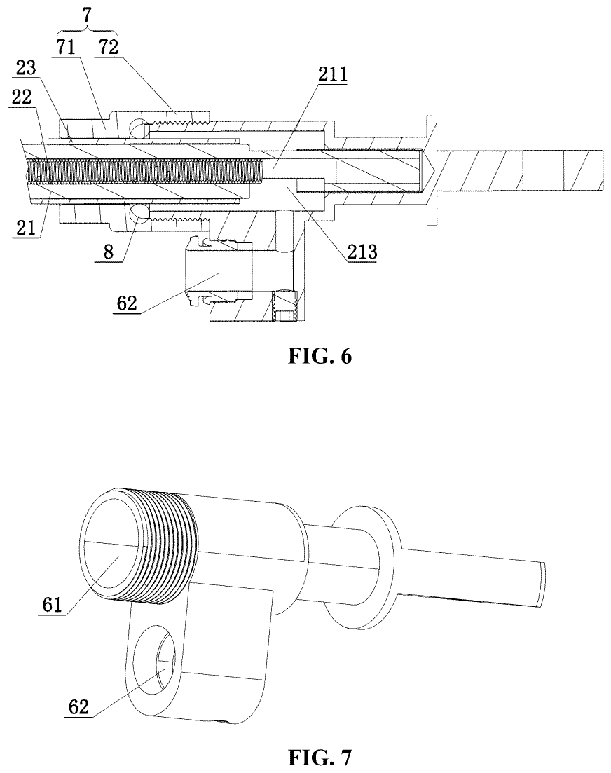

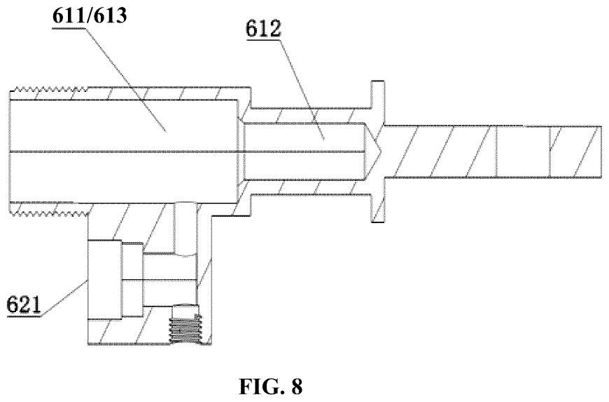

As shown in FIG. 1 to FIG. 8, a circuit connection device is provided according to the present application, which includes a first conductive terminal 1, a cable 2 and a first fixed joint 3. The first conductive terminal 1 is provided with a first receiving socket 11 and a first guide channel 12 in communication with the first receiving socket 11. The first guide channel 12 is in communication with the outside of the circuit connection device via a first external connector 121. One end of the cable 2 is inserted into the first receiving socket 11. The cable 2 is provided with a communication channel 211. The communication channel 211 is in communication with the outside of the circuit connection device through a first communication port 212 and a second communication port 213 respectively. The first communication port 212 is located inside the first receiving socket 11. The first fixed joint 3 is sleeved on the cable 2 and connected to the first conductive terminal 1. The first receiving socket 11 forms a first cooling cavity 113 enclosed by the first fixed joint 3.

In the present application, by providing the first conductive terminal 1 with the first receiving socket 11, to allow the first receiving socket 11 enclosed by the first fixed joint 3 to form the first cooling cavity 113, on this basis and in combination with the first guide channel 12 in the first conductive terminal 1 and the communication channel 211 in the cable 2, the cooling pipeline can directly cool the first conductive terminal 1 inside the first conductive terminal 1, which effectively increases the contact area between the cooling pipeline and the first conductive terminal 1, improves the heat transfer efficiency, so that the heat of the first conductive terminal 1 can be taken away in time, thus ensuring the normal operation of the liquid-cooled charging system. In addition, the assembly structure of the first conductive terminal 1 and the first fixed joint 3 is simple, occupies a small space, and is easy to disassemble and maintain.

Illustratively, the cable 2 includes a metal tube body 21 and a support member 22 arranged in the metal tube body 21, and the inner cavity of the metal tube body 21 is supported by the support member 22 to form the communication channel 211. The metal tube body 21, as an electrical connector, is electrically connected to the first conductive terminal 1 and is the main heat generating component during operation. By making the metal tube body 21 into a tubular shape and using its inner cavity as the communication channel 211 of the cooling pipeline, the metal tube body 21 can be cooled efficiently. Since the structural strength of the tubular structure is relatively low, the communication channel 211 is apt to be disconnected when the metal tube body 21 is bent, so the support member 22 is arranged in the inner cavity of the metal tube body 21 so that the communication channel 211 can safely and reliably guide the cooling liquid.

Illustratively, the cable 2 further includes an insulating outer sheath 23 wrapped around the metal tube body 21, and the first fixed joint 3 is sleeved on the outer sheath 23, which is safer and more reliable.

In some embodiments, the metal tube body 21 is a copper tube, its two ends are respectively a first end and a second end, and the first end and the second end extend from two ends of the outer sheath 23, respectively. The support member 22 is a stainless steel coil spring, which is against an inner wall of the metal tube body 21, and the cooling liquid can pass through the coil spring.

In other embodiments, the support member 22 may further be composed of multiple hard ring sleeves which are arranged in sequence at intervals in the inner cavity of the metal tube body 21.

Illustratively, the first receiving socket 11 includes a first cooling socket body 111 and a first plug-in socket body 112 arranged at the bottom of the first cooling socket body 111. A first end of the metal tube body 21 is plugged into the first plug-in socket body 112, and the first cooling socket body 111 forms the first cooling cavity 113 enclosed by the first fixed joint 3. The metal tube body 21 is plugged into the first conductive terminal 1 through the first plug-in socket body 112, ensuring a reliable electrical connection and avoiding interference from the coolant in the first cooling cavity 113.

Illustratively, the first end of the metal tube body 21 is enclosed, and the first communication port 212 is arranged in a side wall of the metal tube body 21, and is located in the first cooling socket body 111. The above arrangement enables the coolant to flow more smoothly between the first cooling cavity 113 and the communication channel 211.

In some embodiments, the first end of the metal tube body 21 is crimped into the first plug-in socket body 112 through a thin-walled copper tube, the first guide channel 12 is in communication with the socket wall of the first cooling socket body 111, and a communication port via which the first guide channel 12 is in communication with the first cooling socket body 111 and the first communication port 212 are located on opposite sides of the metal tube body 21, so that the coolant can fully flow and diffuse in the first cooling cavity 113.

Illustratively, the first fixed joint 3 includes a first positioning part 31 and a first connecting part 32 connected to each other, the first positioning part 31 is sleeved on the cable 2, and the first connecting part 32 is sleeved on the first conductive terminal 1. The above arrangement enables the first fixed joint 3 to more reliably fix and protect the first conductive terminal 1 through the first connecting part 32.

Illustratively, the circuit connection device further includes a first sealing ring 4, which is sleeved on the cable 2 and sandwiched between the first conductive terminal 1 and the first positioning part 31. With the above arrangement, the first cooling cavity 113 can be sealed, to prevent the coolant in the first cooling cavity 113 from flowing out of the gap between the first fixed joint 3 and the first conductive terminal 1, and also prevent external foreign matter from entering the first cooling cavity 113.

In some embodiments, the first connecting part 32 is screwed to the outer side of the first conductive terminal 1, and the connection sealing performance is better. The first sealing ring 4 is sleeved on the outer sheath 23 of the cable 2.

Illustratively, the circuit connection device further includes a feeding pipeline 5, two first conductive terminals 1 are provided, each first conductive terminal 1 is provided with one cable 2 and one first fixed joint 3, the feeding pipeline 5 has one inlet and two outlets, and the two outlets are communicated with two first external connectors 121 in one-to-one correspondence. By providing the feeding pipeline 5, the coolant can be efficiently transported to the two first conductive terminals 1.

In some embodiments, the feeding pipeline 5 includes one main pipe and two branch pipes, one end port of the main pipe is the inlet, and the other end port of the main pipe is connected to one end of each of the two branch pipes through a pipe joint, and the other end port of each of the two branch pipes is the outlet.

Illustratively, a circuit connection device further includes a second conductive terminal 6 and a second fixed joint 7. The second conductive terminal 6 is provided with a second receiving socket 61 and a second guide channel 62 in communication with the second receiving socket 61. The second guide channel 62 is in communication with the outside of the circuit connection device via a second external connector 621. The other end of the cable 2 is inserted into the second receiving socket 61. The communication channel 211 is in communication with the outside of the circuit connection device through the second communication port 213. The second communication port 213 is located in the second receiving socket 61. The second fixed joint 7 is sleeved on the cable 2 and connected to the second conductive terminal 6. The second receiving socket 61 forms a second cooling cavity 613 enclosed by the second fixed joint 7. The first guide channel 12, the first cooling cavity 113, the communication channel 211, the second cooling cavity 613 and the second guide channel 62 are in communication in sequence to form a cooling pipeline.

In the present application, by providing the second conductive terminal 6 with the second receiving socket 61, to allow the second receiving socket 61 enclosed by the second fixed joint 7 to form the second cooling cavity 613, on this basis and in combination with the second guide channel 62 in the second conductive terminal 6 and the communication channel 211 in the cable 2, the cooling pipeline can directly cool the second conductive terminal 6 inside the second conductive terminal 6, which effectively increases the contact area between the cooling pipeline and the second conductive terminal 6, improves the heat transfer efficiency, so that the heat of the second conductive terminal 6 can be taken away in time, thus ensuring the normal operation of the liquid-cooled charging system. In addition, the assembly structure of the second conductive terminal 6 and the second fixed joint 7 is simple, occupies a small space, and is easy to disassemble and maintain.

Illustratively, the second receiving socket 61 includes a second cooling socket body 611 and a second plug-in socket body 612 arranged at the bottom of the second cooling socket body 611. The second end of the metal tube body 21 is plugged into the second plug-in socket body 612, and the second cooling socket body 611 forms the second cooling cavity 613 enclosed by the second fixed joint 7. The metal tube body 21 is plugged into the second conductive terminal 6 through the second plug-in socket body 612, ensuring a reliable electrical connection and avoiding interference from the coolant in the second cooling cavity 613.

Illustratively, the second end of the metal tube body 21 is enclosed, and the second communication port 213 is arranged in a side wall of the metal tube body 21, and is located in the second cooling socket body 611. The above arrangement enables the coolant to flow more smoothly between the second cooling cavity 613 and the communication channel 211.

In some embodiments, the second end of the metal tube body 21 is crimped into the second plug-in socket body 612 through a thin-walled copper tube, the second guide channel 62 is in communication with the socket wall of the second cooling socket body 611, and a communication port via which the second guide channel 62 is in communication with the second cooling socket body 611 and the second communication port 213 are arranged oppositely, so that the coolant can flow out of the second guide channel 62 timely.

Illustratively, the second fixed joint 7 includes a second positioning part 71 and a second connecting part 72 connected to each other, the second positioning part 71 is sleeved on the cable 2, and the second connecting part 72 is sleeved on the second conductive terminal 6. The above arrangement enables the second fixed joint 7 to more reliably fix and protect the second conductive terminal 6 through the second connecting part 72.

Illustratively, the circuit connection device further includes a second sealing ring 8, which is sleeved on the cable 2 and sandwiched between the second conductive terminal 6 and the second positioning part 71. With the above arrangement, the second cooling cavity 613 can be sealed, to prevent the coolant in the second cooling cavity 613 from flowing out of the gap between the second fixed joint 7 and the second conductive terminal 6, and also prevent external foreign matter from entering the second cooling cavity 613.

In some embodiments, the second connecting part 72 is screwed to the outer side of the second conductive terminal 6, and the connection sealing performance is better. The second sealing ring 8 is sleeved on the outer sheath 23 of the cable 2.

Illustratively, the first conductive terminals 1 are plug-in terminals, the second conductive terminals 6 are copper bars, each first conductive terminal 1 is connected to one second conductive terminal 6 through one cable 2. The first guide channel 12, the first cooling cavity 113, the communication channel 211, the second cooling cavity 613 and the second guide channel 62 are in communication in sequence to form a cooling pipeline for the flow of coolant. The first external connector 121 is the inlet of the coolant, and the second external connector 621 is the outlet of the coolant.

Illustratively, the circuit connection device is a fast charging gun for new energy electric vehicles, the end where the first conductive terminal 1 is located is the head of the charging gun, and the end where the second conductive terminal 6 is located is the tail of the charging gun.

In some embodiments, the circuit connection device further includes a head plug-in shell and a head gun shell, the two first conductive terminals 1 are fixed in the head plug-in shell, the head gun shell is sheathed on the first fixed joint 3 and one end of the cable 2, and is connected to the head plug-in shell.

### Beneficial Effects of the Present Application

By providing the first conductive terminal with the first receiving socket, to allow the first receiving socket enclosed by the first fixed joint to form the first cooling cavity, on this basis and in combination with the first guide channel in the first conductive terminal and the communication channel in the cable, the cooling pipeline can directly cool the first conductive terminal inside the first conductive terminal, which effectively increases the contact area between the cooling pipeline and the first conductive terminal, improves the heat transfer efficiency, so that the heat of the first conductive terminal can be taken away in time, thus ensuring the normal operation of the liquid-cooled charging system. In addition, the assembly structure of the first conductive terminal and the first fixed joint is simple, occupies a small space, and is easy to disassemble and maintain.

The above embodiments of the present application are only examples for clearly illustrating the present application, and are not limitations on the embodiments of the present application. For the person of ordinary skills in the art, other different forms of changes or modifications can be made based on the above description. It is not necessary and impossible to list all the embodiments here. Any modifications, equivalent substitutions and improvements made within the spirit and principles of the present application should be included in the protection scope of the claims of the present application.

What is claimed is:

1. A circuit connection device, comprising:
a first conductive terminal provided with a first receiving socket and a first guide channel in communication with the first receiving socket, wherein the first guide channel is in communication with outside of the circuit connection device via a first external connector;
a cable, wherein one end of the cable is inserted into the first receiving socket, the cable is provided with a communication channel, the communication channel is in communication with outside of the circuit connection device through a first communication port, and the first communication port is located in the first receiving socket, and
a first fixed joint, wherein the first fixed joint is sleeved on the cable and connected to the first conductive terminal, and the first receiving socket forms a first cooling cavity enclosed by the first fixed joint.

2. The circuit connection device according to claim 1, wherein the cable comprises a metal tube body and a support member arranged in the metal tube body, and an inner cavity of the metal tube body is supported by the support member to form the communication channel.

3. The circuit connection device according to claim 2, wherein the first receiving socket comprises a first cooling socket body and a first plug-in socket body arranged at a bottom of the first cooling socket body, a first end of the metal tube body is plugged into the first plug-in socket body, and the first cooling socket body forms the first cooling cavity enclosed by the first fixed joint.

4. The circuit connection device according to claim 3, wherein the first end of the metal tube body is enclosed, and the first communication port is arranged in a side wall of the metal tube body, and is located in the first cooling socket body.

5. The circuit connection device according to claim 1, wherein the first fixed joint comprises a first positioning part and a first connecting part connected to each other, the first positioning part is sleeved on the cable, and the first connecting part is sleeved on the first conductive terminal.

6. The circuit connection device according to claim 5, further comprising a first sealing ring, wherein the first sealing ring is sleeved on the cable and sandwiched between the first conductive terminal and the first positioning part.

7. The circuit connection device according to claim 1, further comprising a feeding pipeline, wherein two first conductive terminals are provided, each of the first conductive terminals is provided with one cable and one first fixed joint, the feeding pipeline has one inlet and two outlets, and the two outlets are communicated with two first external connectors in one-to-one correspondence.

8. The circuit connection device according to claim 1, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

9. The circuit connection device according to claim 8, wherein the second fixed joint comprises a second positioning part and a second connecting part connected to each other, the second positioning part is sleeved on the cable, and the second connecting part is sleeved on an outer side of the second conductive terminal.

10. The circuit connection device according to claim 9, further comprising a second sealing ring, wherein the second sealing ring is sleeved on the cable and sandwiched between the second conductive terminal and the second positioning part.

11. The circuit connection device according to claim 10, wherein the second connecting part is screwed to the outer side of the second conductive terminal.

12. The circuit connection device according to claim 8, wherein the first conductive terminals are plug-in terminals, the second conductive terminals are copper bars, each first conductive terminal is connected to one second conductive terminal through the cable.

13. The circuit connection device according to claim 12, wherein the first external connector is the inlet of the coolant, and the second external connector is the outlet of the coolant.

14. The circuit connection device according to claim 12, wherein the circuit connection device is a fast charging gun for new energy electric vehicles, an end where the first conductive terminal is located is a head of the charging gun, and an end where the second conductive terminal is located is the tail of the charging gun.

15. The circuit connection device according to claim 2, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

16. The circuit connection device according to claim 3, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

17. The circuit connection device according to claim 4, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

18. The circuit connection device according to claim 5, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

19. The circuit connection device according to claim 6, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.

20. The circuit connection device according to claim 7, further comprising:
a second conductive terminal provided with a second receiving socket and a second guide channel in communication with the second receiving socket, wherein the second guide channel is in communication with outside of the circuit connection device via a second external connector, the other end of the cable is inserted into the second receiving socket, the communication channel is in communication with outside of the circuit connection device through the second communication port, and the second communication port is located in the second receiving socket;
a second fixed joint sleeved on the cable and connected to the second conductive terminal, wherein the second receiving socket forms a second cooling cavity enclosed by the second fixed joint; and
the first guide channel, the first cooling cavity, the communication channel, the second cooling cavity and the second guide channel are in communication in sequence to form a cooling pipeline.
